(19) United States
(12) Patent Application Publication
(10) Pub. No.: US 2005/0063556 A1
(43) Pub. Date: Mar. 24, 2005

(54) Audio device

(76) Inventors: Peter C. McEachen, Macedonia, OH (US); Steve Smith, Stow, OH (US); Chi Kong (Stanley) Hui, Hong Kong (HK); Mike Keller, Tallmadge, OH (US); Jason Kanoza, Cuyahoga Falls, OH (US)

Correspondence Address: Cynthia S. Murphy;Renner, Otto, Boisselle & Sklar, LLP, Nineteenth Floor, 1621 Euclid Avenue, Cleveland, OH, 44115-2191, US

(21) Appl. No.: 10/669,513

(22) Filed: Sep. 23, 2003

(51) Int. Cl. H03G 3/00; H04R 3/00

(52) U.S. Cl. 381/104; 381/107

(57) ABSTRACT

An audio device having a primary audio purpose of producing a programmed audio output for a listener. The audio device comprises sound-generating components that generate the programmed audio output, and these components include an emitter that audibly emits this programmed output at a playing volume. A proximity sensor senses the distance to the listener, and this sensed distance corresponds to the distance between the listener and the emitter. Volume-adjusting components adjust the playing volume to prevent it from being at an unacceptable level for the sensed distance.

### FIELD OF THE INVENTION

The present invention relates generally as indicated to an audio device and, more particularly, to an audio device having the primary audio purpose of providing a programmed audio output.

### BACKGROUND OF THE INVENTION

An audio device can have a primary audio purpose of producing a programmed output. For example, radios and televisions are programmed to produce a primary audio output based on received-radio signals. Tape recorders, CD players, DVD players and/or MP3 players are programmed to produce a primary audio output based on previously recorded information. Telephones are programmed to produce a primary audio-output based on sound being substantially concurrently produced on another telephone momentarily connected thereto. With particular reference to toys, many are programmed to produce music, voices, animal imitations, or other sounds for a child's enjoyment, and this programmed output is stored within an internal memory for selective recall during play with the child.

While a certain volume level may be suitable when a listener is positioned a specific distance away from an audio device, this same volume level may be unacceptable when the listener moves closer to, or farther away from, the audio device. For example, if the listener moves closer to the audio device, this same volume level could be too loud, thereby making it annoying, uncomfortable, or even damaging to the listener's ear(s). Additionally or alternatively, if the listener moves farther away from the audio device, the same volume level could be too soft, thereby forcing the listener to “strain” his/her ears to hear and/or even being unable to hear.

### SUMMARY OF THE INVENTION

The present invention provides an audio device incorporating volume-adjusting components which adjust the playing volume to prevent it from being at an unacceptable level when the listener is at a certain distance from the device's sound-emitter. In this manner, the volume level can be adjusted if the listener moves closer to or farther from the audio device, as often happens during use of such devices. Moreover, the volume-adjusting components of the present invention can be easily incorporated into the design of conventional and/or standard audio devices at a minimal cost to the manufacturer.

More particularly, the present invention provides an audio device having a primary audio purpose of producing a programmed audio output for a listener. The audio device comprises sound-generating components that generate the programmed audio output, and these components include an emitter that audibly emits this programmed output at a playing volume. A proximity sensor senses the distance to a listener, and this sensed distance corresponds to the distance between the listener and the emitter. Volume-adjusting components adjust the playing volume so as to prevent the playing volume from being at an unacceptable level for the sensed distance.

In this manner, the playing volume can be reduced if it is too high and/or increased if it is too low. For example, the volume-adjusting components can determine whether the playing volume is at an unsafe volume level (i.e., a level whereat harm, hurt, or damage to a listener's ear(s) becomes a potential risk) for the sensed distance of the listener and, if so, will reduce it to a safer level. When the listener moves away from the audio device, the volume can return to its set level. Additionally or alternatively, the volume-adjusting components can determine whether the playing volume is at an uncomfortable listening level (i.e., a level too low for comfortable, unstrained listening) for the sensed distance of the listener and, if so, will increase it to a more comfortable level. Moreover, the volume-adjusting components can maintain the playing volume at a preferable level (e.g., not too loud, not too soft) as the location of the listener relative to the audio device changes.

These and other features of the invention are fully described and particularly pointed out in the claims. The following description and annexed drawings set forth in detail certain illustrative embodiments of the invention, these embodiments being indicative of but a few of the various ways in which the principles of the invention may be employed.

### DRAWINGS

FIG. 1 is a schematic view of an audio device according to the present invention and a listener situated at a distance therefrom.

FIG. 2 is a schematic view of the audio device with the listener situated at a distance closer thereto.

FIG. 3 is schematic diagram of the operational components of the audio device.

FIG. 4 is a flow chart of volume adjustments according to one embodiment of the invention.

FIG. 5 is a flow chart of volume adjustments according to another embodiment of the invention.

FIG. 6 is a flow chart of the operation of the volume control safety system according to another embodiment of the invention.

### DETAILED DESCRIPTION

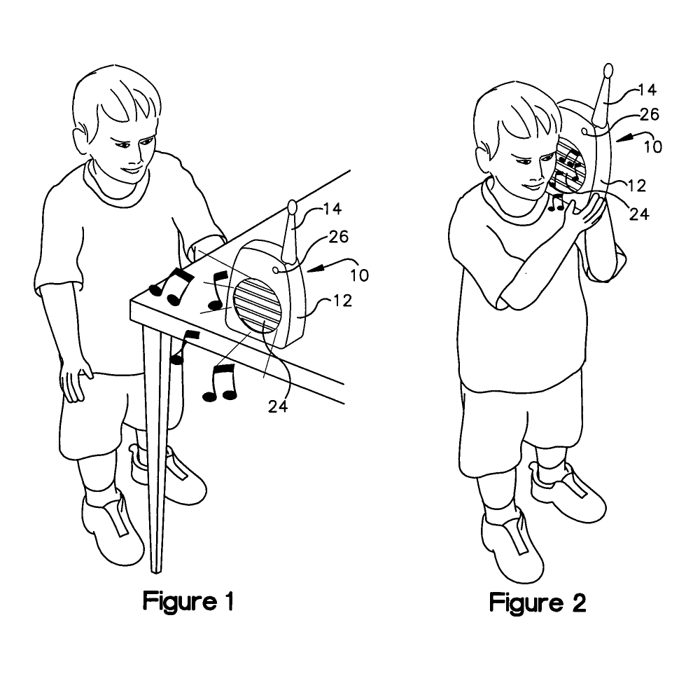

Referring now to the drawings, and initially to FIGS. 1 and 2, an audio device 10 according to the present invention is shown. The illustrated audio device 10 is a radio, which is programmed to produce a primary audio-output based on wirelessly received signals and, to this end, comprises a housing 12 and an antenna 14 for receipt of such signals. As is explained in more detail below, the audio device 10 can automatically adjust its playing volume so as to prevent it from being at an unacceptable level for the listener's relative position. For example, the volume level can be adjusted if the listener moves closer to, or farther from, the audio device 10, as often happens during the use of such devices.

It should be immediately noted that the present invention can find application in a variety of other audio devices. For example, the audio device 10 could be a television which, like the illustrated radio, is programmed to produce a primary audio output based on wirelessly-received or cable-conveyed signals. Audio devices having a primary audio output based on other sources are also possible with, and contemplated by, the present invention. For example, the audio device 10 could be a toy that is programmed to selectively recall music, voices, animal imitations, or other sounds stored in an internal memory. Other possible audio devices include a tape recorder, a CD player, a MP3 player and/or a DVD player which produce a primary audio output from previously recorded information. Further, the audio device 10 could be a telephone, a baby monitor, and/or a walkie-talkie which produce a primary audio-output based on sounds substantially concurrently produced on another presently-connected device. These programmed outputs are distinguishable from, for example, an output from a telephone ringer, which simply audibly indicates or announces that a call (i.e., the primary audio purpose of the telephone) is incoming.

In FIG. 1, a listener is situated at a first distance from the audio device 10, and the programmed output is emitted at a certain volume. In FIG. 2, the listener is situated at a second distance closer to the audio device 10 and the programmed output is emitted at a different volume. Specifically, when the listener moves from the position in FIG. 1 to the position in FIG. 2, the volume adjustment can comprise reducing the playing volume to prevent, for example, a hurtful-to-the-ear volume. Additionally or alternatively, when the listener moves from the position in FIG. 2 to the position in FIG. 1, the volume adjustment can comprise increasing the playing volume to insure, for example, an appropriate playing volume for listening pleasure purposes. (This could comprise returning the volume to a level set by the listener.)

The illustrated listener is a child and it may be noted that the present invention may find special application with young listeners, as they may not appreciate what constitutes an acceptable volume level. That being said, adult audio devices and/or adult listeners are certainly contemplated by, and within the scope of, the present invention. In fact, as explained in more detail below, the invention may also find special application with listeners who are partially hearing-impaired, teenage listeners who traditionally tend to blast audio devices too loud, and/or with listeners who move about while enjoying a programmed output from a stationary audio device.

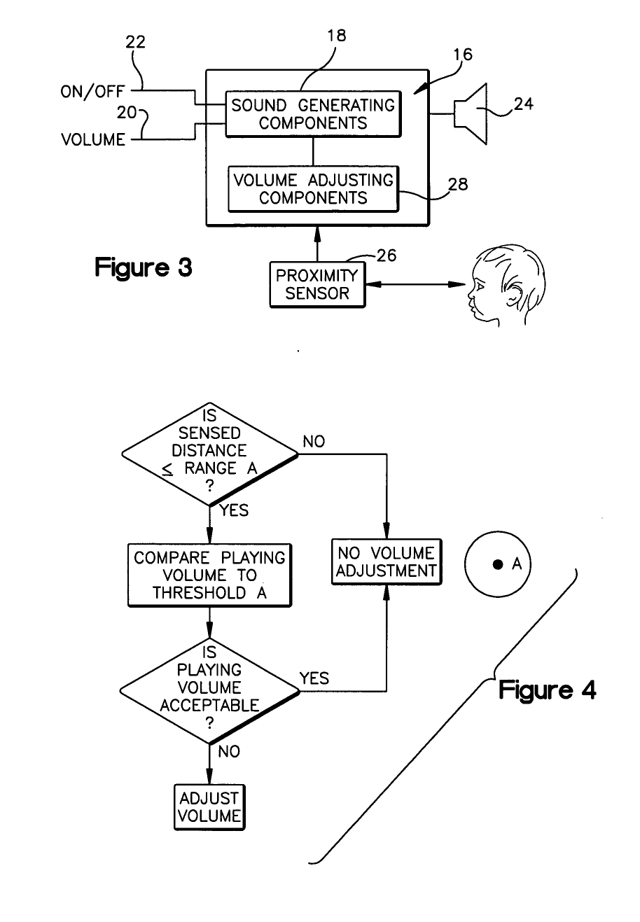

Referring now to FIG. 3, the audio device 10 additionally comprises a sound generator 16 having sound-generating components 18 that generate the programmed audio output. The sound-generating components 18 will vary depending on the nature and/or purpose of the audio device 10 and, in any event, these components can be of a conventional design. In the illustrated embodiment, these components comprise a volume setter 20, an on/off input 22, and an emitter 24 (e.g., a speaker) which audibly emits the programmed output at a playing volume. (See e.g., FIGS. 1 and 2.)

The audio device 10 further comprises a proximity sensor 26 which senses the distance of a listener therefrom. The proximity sensor 26 can be any suitable sensor capable of sensing this distance by, for example, heat, light, sound, capacitiveness and/or inductiveness. If light is used as the sensing component for a toy that will be used in dark conditions (e.g., a bedroom), supplemental lighting may be necessary so that the sensor 26 can still sense light changes. In any event, when the sound generator 16 is turned on, (e.g., by the on/off input 22), power is sent to the proximity sensor 26 which senses the distance between it and the listener. This distance information is then conveyed (i.e., input) to sound-generating components 18 and is often in the form of a control signal which increases as the sensed distance decreases (i.e., as the listener gets closer).

The distance sensed by the proximity sensor 26 corresponds to the distance of the listener to the emitter 24. This correspondence can be accomplished by placing the proximity sensor 26 at substantially the same location as the emitter 24, whereby the sensed distance will essentially equal the distance between the listener and the emitter 24. (See e.g., FIGS. 1 and 2.) Alternatively, the proximity sensor 26 could be placed at another location (near or remote from the sound-generating components 18), whereby the sensed distance, plus or minus the distance between the emitter 24 and the proximity sensor 26, will essentially equal the distance between the listener and the emitter 24. In fact, if the audio device 10 is non-mobile and will remain stationary during and between programmed outputs (e.g., a television), the proximity sensor 26 could be positioned on a wall, a shelf, a ceiling or other such location. It may also be noted that in some situations, the direction (not just the distance) will be important depending upon where a listener is located relative to the emitting direction of the emitter. The proximity sensor 26 can also be designed to take this directional data into consideration.

In the schematically illustrated embodiment, the sound-generating components 18 are part of the sound generator 16. That being said, separate and/or independent sound-generating components 18 are certainly possible with, and contemplated by, the present invention. Additionally, it may be noted that at least some of these sound-generating components 18 also could contribute to the adjustment of the playing volume to the desired level set on the volume setter 20.

Referring now to FIG. 4, the operation of the volume-adjusting components 28 according to one embodiment of the invention is schematically shown. If the sensed distance is within a predetermined range A, it is then determined whether the playing volume is acceptable by comparing it to pre-established threshold A. If the playing volume is not acceptable, an adjustment is made to the playing volume. If the listener is not within the range A and/or if the playing volume is at an acceptable level based on the threshold A, no volume adjustments are made.

The length or span of range A can be different, depending upon the intended use of the audio device 10 and/or the distance between the emitter 24 and the proximity sensor 26. For example, if the sound-generating components 18 are designed to solely protect against high volumes at very close distances, range A can be very short, such as 2 inches. Alternatively, if the sound-generating components 18 are designed to provide a comfortable listening volume within a twenty-feet radius, the range A can be longer, such as ten feet. Also, if the sound-generating components 18 are intended to protect a listener when he/she is within, for example, 2 inches of the emitter 24, and the emitter 24 is ten inches from the proximity sensor 26, then the range A would be twelve inches.

The threshold A can correspond to a safe volume level for the range A; that is a volume level less than a value whereat harm, hurt, or damage to a listener's ear becomes a potential risk based upon known or tested principles. Preferably, the threshold A is lower than this predetermined safe volume level to provide a precautionary margin and, in any event, the volume adjustment can comprise the reduction of the level of the playing volume to a level at or below the threshold A. The reduction of the playing volume can comprise completely ceasing sound generation (i.e., the adjusted volume level is zero) by, for example, interrupting power to the sound generator 16. Alternatively, the reduction of the playing volume level can comprise lowering the volume to an acceptable level greater than zero.

Alternatively, the threshold A can correspond to a comfortable hearing volume level for the range A; that is a volume whereat unstrained and comfortable listening is possible (i.e., neither excessively loud nor soft). In this case, the volume adjustments can comprise the adjustment of the playing volume to such a comfortable hearing level, based upon the threshold A. For example, the playing volume can be increased or decreased to be equal to this threshold.

It should also be noted that, for the purposes of this invention, thresholds and/or ranges are defined by the resulting volume adjustment, regardless of logic employed when programming the sound-generating components 18. For example, if the sound-generating components 18 are programmed to adjust the playing volume when it is greater than or equal to 10 decibels, the threshold could be considered 9.9 decibels and the playing volume would be adjusted when it exceeds this threshold. Likewise, if the sound-generating components 18 are programmed to adjust the playing volume to a certain level when the listener is at a distance less than 5 inches, the relevant range could be considered 4.9 inches and the playing volume would be adjusted when the listener is at a range equal to or less than this range.

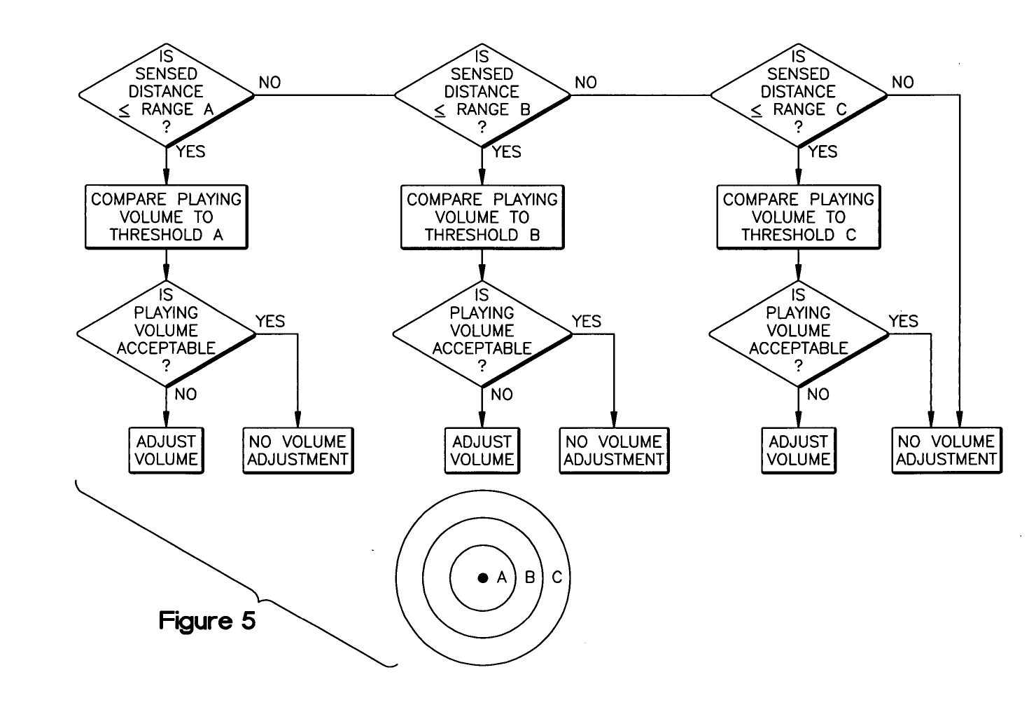

Referring now to FIG. 5, the operation of the volume-adjusting components 28 according to another embodiment of the invention is schematically shown. In this embodiment, the components 28 adjust the playing volume to different levels when the listener is at different distances. For example, a plurality of ranges can be defined, such as a first predetermined range A closest to the emitter 24, a second predetermined range B surrounding the first range A, and a third predetermined range C surrounding the second range B. (Thus, range C is greater than range B and range B is greater than range A.) Range A can be assigned a threshold A, range B can be assigned a different threshold B (e.g., greater than threshold A), and range C can be assigned a different threshold C (e.g., greater than threshold B). These thresholds can correspond to safe volume levels (preferably with precautionary margins) and/or comfortable listening levels for the respective ranges.

If the listener is within the first range A and the playing volume is at an unacceptable level based on a comparison to threshold A, the sound-generating components 18 automatically adjust the playing volume to an acceptable level for range A. If the listener is within the second range B (i.e., a distance greater than range A but less than or equal to range B) and the playing volume is at an unacceptable level based on a comparison to threshold B, the sound-generating components 18 automatically adjust the playing volume level to an acceptable volume for range B. If the listener is within the third range C (i.e., a range greater than range B but less than or equal to range C) and the playing volume is at an unacceptable level based on a comparison to threshold C, the sound-generating components 18 automatically adjust the playing volume level to an acceptable volume for range C.

As discussed above in connection with FIG. 4, the length or span of a particular range can vary depending upon the intended use of the audio device 10 and/or the distance between the emitter 24 and the proximity sensor 26. Also, the number of ranges and/or the spacing of the ranges A, B and C can vary, depending upon the application of the audio device 10. There could be less than three ranges (e.g., two) or more than three ranges (e.g., four, ten, twenty, etc.). The ranges could be different distances apart. For example, the ranges A, B, and C could be 2 inches, 3 inches and 4 inches in certain audio device designs, they could be 1 foot, 4 feet and 12 feet in other designs, and/or they could be 10 feet, 20 feet, 30 feet in other designs. Some or all of the ranges can be uniformly spaced (e.g., 2 inches, 4 inches, 6 inches) and/or can be unequally spaced (e.g., 2 inches, 6 inches, 13 inches), etc. The variance of adjusted volume parameters could, or course, correspond to the length of a particular range and/or the spacing among the ranges.

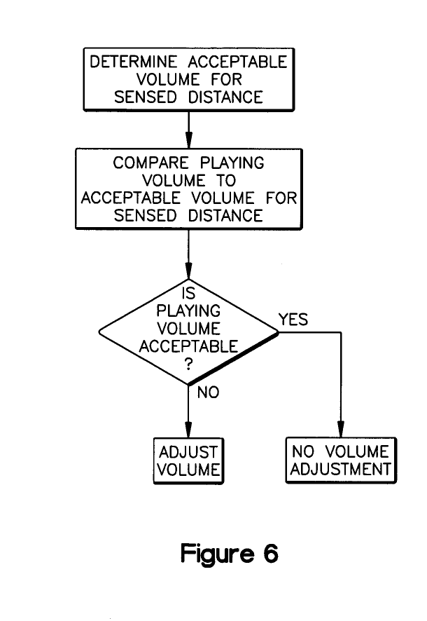

Referring now to FIG. 6, the operation of the volume-adjusting components 28 according to another embodiment of the invention is schematically shown. In this embodiment, the components 28 determine a threshold for each distance sensed by the proximity sensor 26. The data for this determination can be provided by previous testing of the audio device 10 at different intermittent distance points and then interpolating to obtain decibel levels for the points therebetween. Additionally or alternatively, the data can be provided in a similar manner based upon established volume levels at different distance points. In either or any event, the sound-generating components 18 adjust the playing volume if, based upon the distance-specific threshold, it is unacceptable.

Thus in the embodiment shown schematically in FIG. 6, the sound-generating components 18 also adjust the playing volume to different levels when the listener is at different distances (as with the embodiment shown schematically in FIG. 5). Also, this volume-adjusting technique can be considered to utilize predetermined ranges, as there is a predetermined range between each sense-able distance. (While mathematically there may be an infinite number of points in any particularly distance, instrumentation will limit the number of sense-able distance points and thereby define a predetermined range therebetween.)

It may be noted that when the volume adjustment comprises a comparison of different thresholds (e.g., FIGS. 5 and 6), these thresholds can (and often will) sequentially increase as the ranges expand away from the audio device 10. However, this may not always be the case. For example, the volume-adjusting components 28 could be programmed so as to provide a volume spike at an intermediate range to accommodate a noisy environment thereat. Additionally or alternatively, the volume-adjusting components 28 could be programmed to dramatically reduce the playing volume (to zero or otherwise) when the listener is at a location outside a listening range of the audio device 10. This would be useful with a child who wanders to another room after losing interest in a sound-generating toy and/or a teenager who repeatedly forgets to turn off a stereo when he/she departs from home for the evening.

Depending upon design intentions, the audio device 10 can remain in its adjusted-volume condition until the volume is reset (e.g., by the volume setter 20) and/or until the audio device 10 is reset (e.g., by the on/off input 22). In this case, a timer might be employed to cause a slight delay (e.g., ten seconds) between the reset being input and the reset being initiated (e.g., the audio device 10 being turned back on and/or the volume being increased). In this manner, the person performing the reset will not trigger another adjustment in volume during such resetting. Alternatively, the audio device 10 can return to its user set volume level upon the listener moving outside the predetermined range.

A further post-adjustment option is for the sound-generating components 18 to continue to automatically adjust the volume to an acceptable level as the listener moves away or towards the audio device 10. In this case, the need for the volume setter 20 could be eliminated, as it would no longer be necessary. Such automatic volume adjustments could be especially useful in a toy so that the child and/or the parent does not have to worry about setting a desired volume level. Also, these automatic volume adjustments could be particularly enjoyed by a listener who moves about (e.g., does housework) while listening to a stationary audio device. Further, these adjustments could be helpful to a person with hearing loss to insure that the playing volume will always be at a sufficient level (i.e., loud enough) for him/her to enjoy. A multiplier input (not shown) could be provided to allow a hard-of-hearing person to format the thresholds to suit his/her particular hearing needs.

One may now appreciate that the audio device 10, and particularly its sound-generating components 18, can automatically adjust the playing volume of a device so as to prevent it from reaching an unacceptable level when the listener is at a certain distance from the device's emitter 24. These adjustments can be designed to prevent harmful volume levels at close ranges, allow adequate volume levels at distant ranges, provide an automatic shut-off or turn-down when a listener moves beyond a listening range, and/or maintain comfortable hearing volume levels at all ranges.

Although the invention has been shown and described with respect to certain preferred embodiments, it is evident that equivalent and obvious alterations and modifications will occur to others skilled in the art upon the reading and understanding of this specification.

1. An audio device having a primary audio purpose of producing a programmed audio output for a listener, said device comprising:
sound-generating components that generate the programmed audio output and include an emitter that audibly emits the programmed output at a playing volume;
a proximity sensor that senses a distance between it and the listener, this sensed distance corresponding to a distance between the listener and the emitter; and
volume-adjusting components which adjust the playing volume to prevent it from being at an unacceptable level at the sensed distance.

2. An audio device as set forth in claim 1, wherein the playing volume remains in its adjusted condition until a reset is performed.

3. An audio device as set forth in claim 2, wherein the volume-adjusting components are configured to provide a delay between performance of the reset and initiation of the reset.

4. An audio device as set forth in claim 1, wherein the volume-adjusting components are configured to reduce the playing volume if the listener is within a certain range and if the playing volume is at an unacceptable level for this range.

5. An audio device as set forth in claim 4, wherein the volume-adjusting components are configured to reduce the playing volume to zero if the listener is within said certain range and if the playing volume is at an unacceptable level for this range.

6. An audio device as set forth in claim 5, wherein the reduction of volume to zero is accomplished by interrupting power to at least some of the sound generating components.

7. An audio device as set forth in claim 4, wherein the reduction of volume is accomplished by reducing the playing volume to a level greater than zero.

8. An audio device as set forth in claim 7, wherein the reduced playing volume is equal to or less than a threshold.

9. An audio device as set forth in claim 8, wherein the threshold corresponds to a pre-established safe volume level for said certain range.

10. An audio device as set forth in claim 1, wherein the volume-adjusting components are configured to increase the playing volume if the listener is outside a certain range and if the playing volume is unacceptably low for this range.

11. An audio device as set forth in claim 1, wherein the sound-generating components comprise a volume setter for setting a desired level for the playing volume and wherein the volume-adjusting components override the volume setter.

12. An audio device as set forth in claim 11, wherein the volume-adjusting components are configured to reduce the playing volume if the listener is within a certain range of the emitter and if the set playing volume is at an unacceptable level for this range, and wherein the playing volume returns to the set volume upon the listener moving outside the certain range.

13. An audio device as set forth in claim 1, wherein the volume-adjusting components adjust the playing volume to different levels when the listener is at different distances from the sound generator.

14. An audio device as set forth in claim 1, wherein there is a threshold A for a predetermined range A, and wherein, when the sensed distance is less than or equal to range A, the volume-adjusting components adjust the playing volume if necessary based upon a comparison with the threshold A.

15. An audio device as set forth in claim 14, wherein the volume-adjusting components reduce the playing volume when the playing volume exceeds the threshold A.

16. An audio device as set forth in claim 14, wherein the volume-adjusting components increase the playing volume when the playing volume is less than the threshold A.

17. An audio device as set forth in claim 16, wherein the volume-adjusting components reduce the playing volume when the playing volume exceeds the threshold A.

18. An audio device as set forth in claim 14, wherein there is a threshold B for a range B greater than the range A, and wherein, when the sensed distance is greater than range A but less than or equal to range B, the volume-adjusting components adjust the playing volume based upon a comparison with the threshold B.

19. An audio device as set forth in claim 18, wherein:
when the sensed distance is less than or equal to range A, the volume-adjusting components reduce the playing volume when the playing volume exceeds the threshold A; and
when the sensed distance is greater than range A and less than or equal to range B, the volume-adjusting components reduce the playing volume when the playing volume exceeds the threshold B.

20. An audio device as set forth in claim 18, wherein:
when the sensed distance is less than or equal to range A, the volume-adjusting components increase the playing volume when the playing volume is less than or equal to the threshold A; and
when the sensed distance is greater than range A and less than or equal to range B, the volume-adjusting components increase the playing volume when the playing volume is less than or equal to the threshold A.

21. An audio device as set forth in claim 18, wherein:
when the sensed distance is less than or equal to range A, the volume-adjusting components reduce the playing volume when it exceeds the threshold A and increase the playing volume when it is less than or equal to the threshold A;
when the sensed distance is greater than range A and less than or equal to range B, the volume-adjusting components reduce the playing volume when the playing volume exceeds the threshold B and increase the playing volume when it is less than or equal to threshold A.

22. An audio device as set forth in claim 18, wherein there is a predetermined acceptable volume threshold C for a predetermined range C greater than the range B, and wherein, when the sensed distance is greater than range B but less than or equal to range C, the volume-adjusting components adjust the playing volume based on the threshold C.

23. An audio device as set forth in claim 1, wherein the volume-adjusting components determine an unacceptable volume level for the distance sensed by the proximity sensor and then adjust the playing volume based upon the sensed distance.

24. An audio device as set forth in claim 23, wherein the unacceptable volume level occurs when the playing volume exceeds an acceptable volume threshold for a sensed distance and the volume adjustment comprises decreasing the playing volume.

25. An audio device as set forth in claim 24, wherein data used to determine the acceptable volume threshold for a sensed distance is provided by previous testing to establish safe decibel levels.

26. An audio device as set forth in claim 23, wherein the unacceptable volume level occurs when the playing volume is less than an acceptable volume threshold for a sensed distance and the volume adjustment comprises increasing the playing volume.
